(19) United States
(12) Patent Application Publication
(10) Pub. No.: US 2019/0237326 A1
(43) Pub. Date: Aug. 1, 2019

(54) SELECTIVE FILM FORMING METHOD AND FILM FORMING APPARATUS

(71) Applicant: TOKYO ELECTRON LIMITED, Tokyo (JP)

(72) Inventors: Takayuki KOMIYA, Nirasaki City (JP); Hirokazu UEDA, Nirasaki City (JP); Atsushi ENDO, Nirasaki City (JP)

(21) Appl. No.: 16/257,790

(22) Filed: Jan. 25, 2019

(30) Foreign Application Priority Data
Jan. 31, 2018 (JP) 2018-014856

(51) Int. Cl. H01L 21/02; H01L 21/311; H01L 21/67; H01L 21/687; H01J 37/32

(52) U.S. Cl. CPC H01L 21/02274; H01L 21/02112; H01J 37/32201; H01L 21/67069; H01L 21/68714; H01L 21/31122

(57) ABSTRACT

There is provided a selective film forming method, comprising a first step of preparing a work piece having a plurality of recesses; a second step of forming a boron-based film having a first predetermined film thickness in a portion of the work piece other than the recesses by plasma CVD; and a third step of etching a side surface of the formed boron-based film having the first predetermined film thickness, wherein the boron-based film is formed in the portion of the work piece other than the recesses in a self-aligned and selective manner.

### CROSS-REFERENCE TO RELATED APPLICATION

This application is based upon and claims the benefit of priority from Japanese Patent Application No. 2018-014856, filed on Jan. 31, 2018, the entire contents of which are incorporated herein by reference.

### TECHNICAL FIELD

The present disclosure relates to a selective film forming method and a film forming apparatus.

### BACKGROUND

In the manufacture of a semiconductor device, a predetermined pattern is formed by photolithography and etching. In recent years, the miniaturization of a semiconductor device has progressed, resulting in a semiconductor device having a size of 14 nm or less, specifically 10 nm or less. Thus, the limit of photolithography accuracy has been reached.

For this reason, there is a demand for a method of forming a wiring or the like connected to a transistor in a self-aligning manner. Surface selective growth of a metal/insulating film or shape selective growth is desired. As a technique capable of performing such selective growth, there is known a technique in which a step of adsorbing a precursor gas composed of an organometallic gas or an organic semimetal gas having a high adhesion probability to a surface of a substrate having a plurality of depressions (recesses) formed thereon, and a step of oxidizing or nitriding the precursor gas by an oxidizing gas or a nitriding gas are repeated at a high speed by a rotary ALD apparatus, whereby a protective film composed of an oxide film or a nitride film such as a TiO₂ film, a SiN film, a TiN film or the like is selectively formed in the portion other than the recesses.

However, in the aforementioned technique, a special process of repeating the step of absorbing the precursor gas and the step of oxidizing or nitriding the precursor gas at a high speed is necessary, and the applied apparatus is limited to a rotary type special ALD apparatus. In addition, in the aforementioned technique, an oxide film or a nitride film such as a TiO₂ film, a SiN film, a TiN film or the like is selectively formed as a protective film to be used at the time of etching. However, in some cases, there is required a protective film having a higher etching resistance than the oxide film or the nitride film described above.

Further, there may be required an application of a sacrificial film which is removed after functioning as a protective film or the like. The oxide film or the nitride film described above is insufficient in the removability (peeling property) and is hardly applicable to such an application.

### SUMMARY

Some embodiments of the present disclosure provide a selective film forming method capable of selectively forming a film having a higher etching resistance without having to use a special process or apparatus and, in addition thereto, provide a selective film forming method and a film forming apparatus capable of selectively forming an easily-removable film.

According to one embodiment of the present disclosure, there is provided a selective film forming method, including: a first step of preparing a work piece having a plurality of recesses; a second step of forming a boron-based film having a first predetermined film thickness in a portion of the work piece other than the recesses by plasma CVD; and a third step of etching a side surface of the formed boron-based film having the first predetermined film thickness, wherein the boron-based film is formed in the portion of the work piece other than the recesses in a self-aligned and selective manner.

According to another embodiment of the present disclosure, there is provided a selective film forming method, including: a first step of preparing a work piece having a plurality of recesses; a second step of selectively forming a boron film having a first predetermined film thickness in a portion of the work piece other than the recesses by plasma CVD; a third step of etching a side surface of the formed boron film having the first predetermined film thickness; and a fourth step of performing an oxidation process on the boron film, wherein a boron oxide film is formed in the portion of the work piece other than the recesses in a self-aligned and selective manner.

According to another embodiment of the present disclosure, there is provided a film forming apparatus, including: a chamber configured to accommodate a work piece having a plurality of recesses; a mounting table configured to support the work piece in the chamber; a gas supply mechanism configured to supply a processing gas including at least a boron-containing gas and an etching gas into the chamber; an exhaust device configured to evacuate an inside of the chamber; a plasma generator configured to generate plasma in the chamber; and a controller configured to perform control so that a boron-based film is formed in a portion of the work piece other than the recesses by causing the gas supply mechanism to supply the processing gas including the boron-containing gas into the chamber and by causing the plasma generator to generate plasma of the processing gas including the boron-containing gas, and a side surface of the boron-based film is etched by causing the gas supply mechanism to supply the etching gas into the chamber, wherein the boron-based film is formed in the portion of the work piece other than the recesses in a self-aligned and selective manner.

According to another embodiment of the present disclosure, there is provided a film forming apparatus, including: a chamber configured to accommodate a work piece having a plurality of recesses; a mounting table configured to support the work piece in the chamber; a gas supply mechanism configured to supply a processing gas including at least a boron-containing gas, an etching gas and an oxidizing gas into the chamber; an exhaust device configured to evacuate an inside of the chamber; a plasma generator configured to generate plasma in the chamber; and a controller configured to perform control so that a boron film is selectively formed in a portion of the work piece other than the recesses by causing the gas supply mechanism to supply the processing gas including the boron-containing gas into the chamber and by causing the plasma generator to generate plasma of the processing gas including the boron-containing gas, a side surface of the boron film is etched by causing the gas supply mechanism to supply the etching gas into the chamber,and the boron film is oxidized by causing the plasma generator to generate plasma of the oxidizing gas, wherein a boron oxide film is formed in the portion of the work piece other than the recesses in a self-aligned and selective manner.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIGS. 1A to 1C are process sectional views showing a selective film forming method according to a first embodiment of the present disclosure.

FIGS. 2A and 2B are SEM photographs showing the states of a boron film formed by thermal CVD and a boron film formed by plasma CVD.

FIG. 3 is a sectional view showing a state in which forming a boron-based film and etching the boron-based film are repeated in the first embodiment of the present disclosure.

FIGS. 4A to 4D are process sectional views showing a selective film forming method according to a second embodiment of the present disclosure.

FIG. 5 is a sectional view showing a state in which forming a boron-based film, etching the boron-based film, and oxidizing the boron-based film are repeated in the second embodiment of the present disclosure.

FIG. 6 is a sectional view showing an example of a film forming apparatus for carrying out the selective film forming method of the first embodiment.

FIG. 7 is a sectional view showing an example of a film forming apparatus for carrying out the selective film forming method of the second embodiment.

FIG. 8 is a sectional view showing another example of the film forming apparatus.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

### First Embodiment

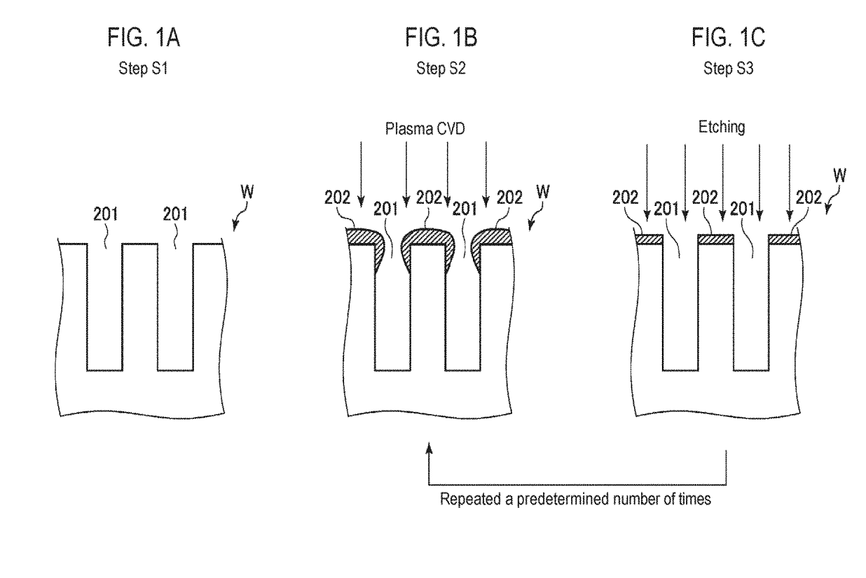

First, a first embodiment of the present disclosure will be described. FIGS. 1A to 1C are process sectional views showing a selective film forming method according to a first embodiment of the present disclosure.

In this embodiment, first, a semiconductor wafer (hereinafter simply referred to as a wafer) W having a plurality of recesses 201 is prepared as a work piece (step S1 and FIG. 1A).

Typical examples of the wafer W include a silicon wafer. The recesses 201 are, for example, trenches formed in a predetermined pattern. The water W may be a semiconductor substrate (for example, a silicon substrate) itself, or may be a semiconductor substrate having a predetermined film such as an interlayer insulating film or the like formed thereon. In the former case, the recesses 201 are formed directly on the semiconductor substrate. In the latter case, the recesses 201 are formed in the predetermined film on the semiconductor.

Next, a boron-based film 202 is formed by plasma CVD (PECVD) (step S2 and FIG. 1B). The boron-based film 202 is a film having boron of 50 at % or more and mainly composed of boron. The boron-based film 202 may be a boron film composed of boron and inevitable impurities, or may be a film formed by intentionally adding another element such as nitrogen (N), carbon (C), silicon (Si) or the like to boron. However, from the viewpoint of obtaining a high etching resistance, a boron film not containing another additive element is preferable. The boron-based film formed by the plasma CVD contains unavoidable impurities derived from a film-forming material or the like, for example, mostly hydrogen (H) of about 5 to 15 at %.

Plasma for the CVD plasma is not particularly limited and may be capacitively coupled plasma or inductively coupled plasma. It is particularly preferable to use microwave plasma CVD capable of generating low-damage high-density plasma which is low in electron temperature and is mainly composed of radicals.

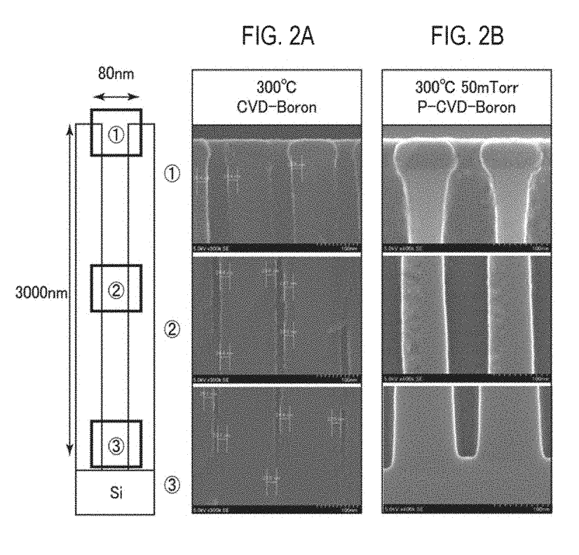

The boron-based film, particularly the boron film, is formed conformally on a work piece (wafer W) having recesses by thermal CVD as shown in FIG. 2A. In plasma CVD, as shown in FIG. 2B, the film formation in the bottom portions or the side wall portions of the recesses 201 of the wafer W as a work piece is extremely suppressed, and the boron-based film is selectively formed in the field portion (convex portion) other than the recesses 201. This is believed to be due to the generation of active species (BH₃) having a very high adhesion probability.

Next, the side surface of the boron-based film 202 is removed by etching (step S3 and FIG. 1C).

As shown in FIG. 1B, the boron-based film 202 in an as-formed state is kept in a state of overhanging in the opening portions of the recesses 201. By removing the overhanging side surface through side etching, as shown in FIG. 1C, it is possible to leave the boron-based film 202 only in the portion (convex portion) other than the recesses 201.

The etching at this time may be carried out physically by argon (Ar) plasma, or may be carried out by using a gas which reacts with boron, such as a fluorine (F)-based gas or hydrogen (H₂). Examples of the F-based gas include an excited NF₃ gas (NF₃ remote plasma). In the case of using H₂, it may be possible to use a gas system in which H₂ is contained in an amount of 1 to 100% and the balance is Ar.

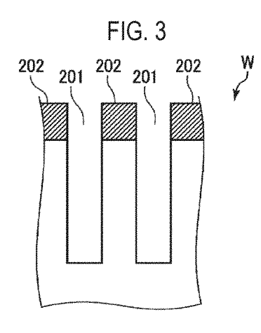

By forming such a boron-based film by plasma CVD in step S2 and performing etching in step S3, the boron-based film 202 can be formed in the portion (convex portion) other than the recesses 201 in a self-aligned and selective manner. Steps S2 and S3 may be performed once. However, by repeating steps S2 and S3, as shown in FIG. 3, the boron-based film 202 having a desired thickness can be formed in the portion (convex portion) other than the recesses 201 in a self-aligned and selective manner. The selective film formation in this embodiment is effective when the recesses 201 are fine recesses having a width of 80 nm or less. Although the film thickness of the boron-based film formed at one time depends on the width of the recesses 201, it is preferable that the film thickness of the boron-based film is in a range of 1 to 10 nm.

When forming the boron-based film 202 by plasma CVD in step S2, a processing gas including a boron-containing gas is used. The processing gas preferably includes a rare gas such as an Ar gas or a He gas for plasma excitation. In the case of using a boron-based film obtained by adding another element to boron, a gas containing an element to be further added is used as the processing gas. The processing gas may further include a hydrogen gas.

Examples of the boron-containing gas include a diborane (B₂H₆) gas, a boron trichloride (BCl₃) gas, an alkylborane gas, a decaborane gas and the like. Examples of the alkylborane gas include a trimethylborane (B(CH₃)₃) gas, a triethylborane (B(C₂H₅)₃) gas, gases represented by B(R1)(R2)(R3), B(R1)(R2)H and B(R1)H₂ (where R1, R2 and R3 are alkyl groups), and the like. Among them, the B₂H₆ gas may be suitably used.

When forming the boron-based film 202, the pressure is preferably in the range of 0.67 Pa to 33.3 Pa (5 mTorr to 250 mTorr), and the temperature is preferably in the range of 500 degrees C. or less. A more preferable range of the temperature is 60 to 500 degrees C. In these ranges of pressure and temperature, it is possible to obtain a denser and flat boron-based film.

At the time of performing the etching in step S3, as described above, the Ar plasma or the F-based gas such as an excited NF₃ gas or the like is used. However, in this step, it is only necessary to remove the overhanging portion of the side surface of the boron-based film 202. Therefore, it is not necessary to strictly set the manufacturing conditions. The pressure at this time is preferably 0.13 to 133 Pa (1 to 1000 mTorr). In the case of using the Ar plasma, it is preferable to apply a high frequency bias to the wafer W to draw Ar ions.

Step S2 and step S3 are preferably performed in the same chamber. This makes it possible to realize selective formation of a boron-based film high throughput. In this case, strict temperature control is unnecessary in step S3. From the viewpoint of increasing the throughput, it is preferable to perform step S3 at a temperature substantially same as a temperature in step S2. In the case of using the Ar plasma in step S3, an Ar gas is used as a rare gas for plasma excitation in step S2 to form a boron-based film. Then, the supply of the boron-containing gas or the like is stopped while maintaining the plasma of the rare gas, and the conditions are appropriately set merely, thereby the etching in step S3 can be performed.

According to the present embodiment, the film formation on the bottom portions or the side wall portions of the recesses 201 is extremely suppressed by utilizing the fact that active species (BH₃) having an extremely high adhesion probability are generated when forming the boron-based film 202 by plasma CVD, whereby the film grows in the portion (convex portion) other than the recesses 201 in a self-aligned and selective manner. Therefore, it is possible to form a film under general plasma CVD conditions without having to use a special process such as high-speed ALD conditions of aforementioned conventional technique or an accompanying special apparatus. Furthermore, the boron-based film, particularly the boron film, has a high etching resistance as compared with the oxide or the nitride of aforementioned conventional technique, and has an etching selection ratio to an Si-containing film or a C-containing film that is widely used for semiconductor devices. Therefore, the boron-based film is highly effective as a protective film. Furthermore, by forming the boron-based film having a high etching resistance in a self-aligned and selective manner, the boron-based film can be used not only as a protective film but also as an etching stopper or a hard mask when etching a fine pattern, and can be applied more widely than the film of aforementioned conventional films.

### Second Embodiment

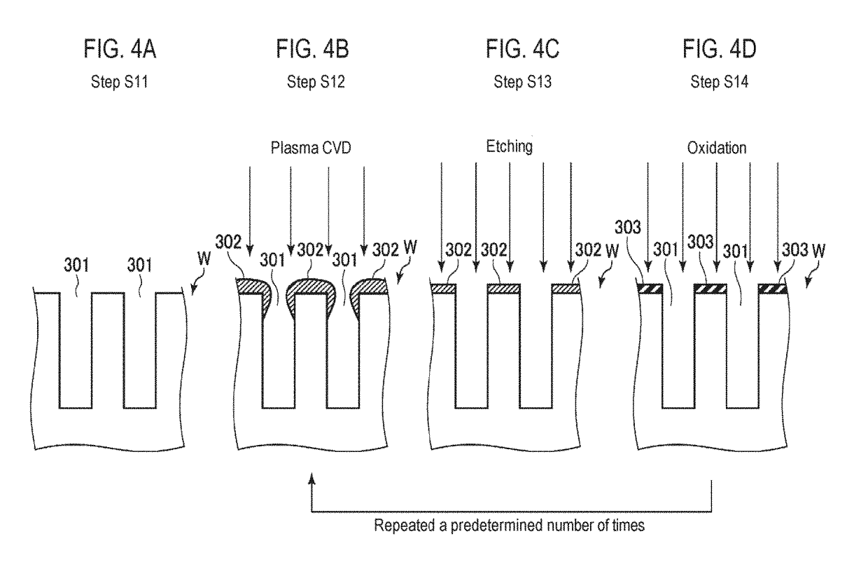

Next, a second embodiment of the present disclosure will be described. FIGS. 4A to 4D are process sectional views showing a selective film forming method according to a second embodiment of the present disclosure.

In the present embodiment, first, as in the first embodiment, a wafer W having a plurality of recesses 301 is prepared as a work piece (step S11 and FIG. 4A).

Then, a boron film 302 is formed by plasma CVD (step S12 and FIG. 4B), and the side surface of the boron film 302 is removed by etching (step S13 and FIG. 4C). Thereafter, the boron film 302 is oxidized to form a boron oxide (B₂O₃) film 303 (step S14 and FIG. 4D).

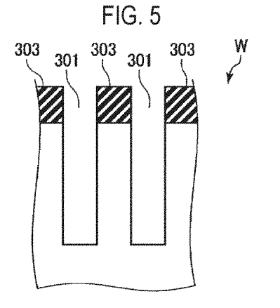

By performing the formation of the boron-based film by plasma CVD in step S12, the etching in step S13 and the oxidation process in step S14, it is possible to form the boron oxide film 303 in the portion (convex portion) other than the recesses 301 in a self-aligned and selective manner. Steps S12, S13 and S14 may be performed once. However, by repeating steps S12, S13 and S14, as shown in FIG. 5, it is possible to form a boron oxide film 303 having a desired thickness in a portion (convex portion) other than the recesses 301 in a self-aligned and selective manner. The selective film formation according to the present embodiment is effective when the recesses 301 are fine recesses having a width of 80 nm or less. Although the film thickness of the boron film formed at one time depends on the width of the recesses 301, it is preferable that the film thickness of the boron film formed at one time is in the range of 1 to 10 nm.

In step S12, it is necessary to form a boron oxide (B₂O₃) film by the oxidation process of step S14. Therefore, a boron film 302 to which no other element is added is formed. As with the boron-based film 202 of the first embodiment, the boron film may be formed by appropriate plasma CVD. However, it is particularly preferable to use microwave plasma CVD capable of generating low-damage high-density plasma which is low in electron temperature and is mainly composed of radicals. The boron film formed by the plasma CVD contains unavoidable impurities derived from a film-forming material or the like, for example, hydrogen (H) of about 5 to 15 at %.

When forming the boron film 302 by plasma CVD, as in the first embodiment, a processing gas including a boron-containing gas is used. The processing gas preferably includes a rare gas such as an Ar gas or a He gas for plasma excitation. The processing gas may further include a hydrogen gas. As the boron-containing gas, it may be possible to use the same one as used in the first embodiment.

When forming the boron film 302, as in the first embodiment, the pressure is preferably in the range of 0.67 Pa to 33.3 Pa (5 mTorr to 250 mTorr), and the temperature is preferably in the range of 500 degrees C. or less. A more preferable range of the temperature is 60 to 500 degrees C. In these ranges of pressure and temperature, it is possible to obtain a denser and flat boron film.

As in step S3 of the first embodiment, the etching in step S13 is performed to remove an overhanging side surface by side etching. The etching in step S13 may be physically performed by argon (Ar) plasma, or may be performed by using a gas reacting with boron, such as a fluorine (F)-based gas or the like.

In the oxidation process of step S14, it is difficult to oxidize boron itself. A temperature of 650 degrees C. or more is necessary for thermal oxidation. Therefore, it is preferable to use an excited oxidizing gas such as O₂ plasma or the like. As the oxidizing gas, in addition to the O₂ gas, it may be possible to use an O₃ gas, an N₂O gas or the like. Since the boron itself is a material which is not easily oxidized, when repeating the boron film formation in step S12 and the etching in step S13, it is preferable that, as in this example, an oxidation process is performed for each boron film formation. From the viewpoint of sufficiently oxidizing the boron film, it is preferable that the thickness of the boron film formed at one time is 10 nm or less. Oxidation can be performed at a low temperature of about 60 to 300 degrees C. by performing the oxidation process through the use of plasma. The pressure at this time is preferably 0.13 to 133 Pa (1 to 1000 mTorr).

Steps S12, S13 and S14 are preferably performed in the same chamber. This makes it possible to realize the selective formation of a boron oxide film with high throughput. In this case, from the viewpoint of increasing the throughput, steps S12, S13 and S14 are preferably performed substantially at the same temperature. Step S13 does not require a strict temperature, and the temperature in step S14 has a wide tolerance range. Therefore, after performing step S12 at a desired temperature, step S13 and step S14 may be performed at the same temperature.

In the above example, steps S12 to S14 are repeated as a preferable example. However, depending on the thickness of the boron film 302 formed at one time or the film thickness of the entire boron film 302, a cycle of performing the oxidation process of step S14 after repeating step S12 and step S13 a predetermined number of times may be repeated a plurality of times. Alternatively, the oxidation process in step S14 may be performed at one time after repeating steps S12 and S13 until the boron film 302 has a final film thickness. In any case, the film thickness of the boron film 302 to be oxidized is preferably 10 nm or less.

According to the present embodiment, the film formation on the bottom portions or the side wall portions of the recesses 301 is extremely suppressed by utilizing the fact that active species (BH₃) having an extremely high adhesion probability are generated when forming the boron film 302 by plasma CVD, whereby the boron film 302 grows in the portion (convex portion) other than the recesses 301 in a self-aligned and selective manner. Furthermore, by oxidizing the boron film thus formed, it is possible to form a boron oxide film having a high etching resistance just like the boron film. Therefore, as in the first embodiment, it is possible to form a film under general plasma CVD conditions without having to use a special process such as high-speed ALD conditions of the aforementioned conventional technique or an accompanying special apparatus. In addition, the boron oxide film has a high etching resistance just like the boron film. Thus, the boron oxide film is highly effective as a protective film. Furthermore, the boron oxide film is water-soluble. Therefore, the boron oxide film can be easily removed by washing the same with water without affecting other films. Accordingly, in addition to the use as a protective film, an etching stopper and a hard mask on the premise that a film remains as in the first embodiment, the boron oxide film may be used as a sacrificial film or a hard mask required to be removed after performing these functions.

### <Film Forming Apparatus>

### One Example of Film Forming Apparatus for Carrying Out the Method of the First Embodiment

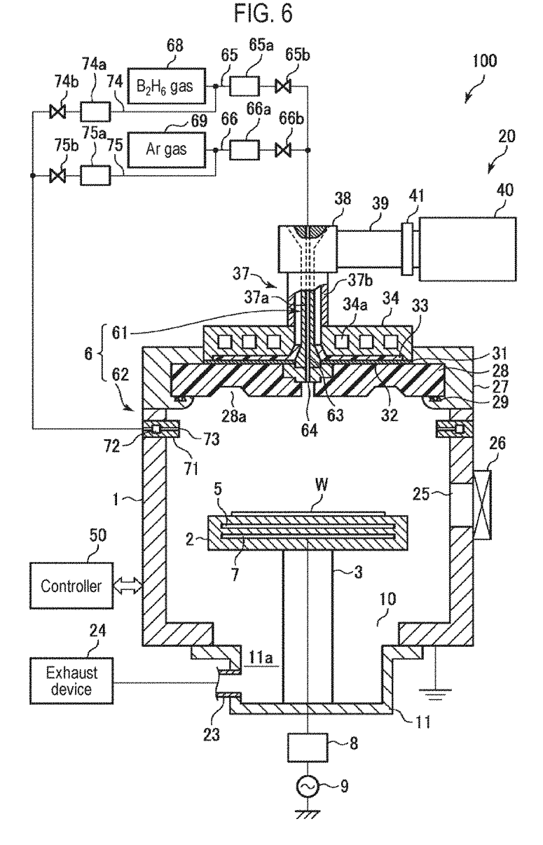

First, an example of a film forming apparatus for carrying out the selective film forming method of the first embodiment will be described. FIG. 6 is a sectional view showing an example of a film forming apparatus for carrying out the selective film forming method of the first embodiment. The film forming apparatus 100 of this example is configured as a microwave plasma apparatus for forming a boron film as a boron-based film and performing side etching.

This film forming apparatus 100 includes a substantially cylindrical chamber 1 which is airtightly configured and grounded. The chamber 1 is made of, for example, a metallic material such as aluminum, its alloy or the like. A microwave plasma source 20 is provided above the chamber 1. The microwave plasma source 20 is configured, for example, as an RLSA (registered trademark) microwave plasma source.

A circular opening 10 is formed substantially at the center of the bottom wall of the chamber 1. On the bottom wall, there is provided an exhaust chamber 11 communicating with the opening 10 and projecting downward.

In the chamber 1, there is provided a disk-shaped mounting table 2 made of ceramic such as AlN or the like for horizontally supporting a wafer W as a substrate to be processed. The mounting table 2 is supported by a cylindrical support member 3 made of ceramic such as AlN or the like extending upward from the center of the bottom portion of the exhaust chamber 11. A resistance heating type heater 5 is buried in the mounting table 2. The heater 5 generates heat by being supplied with electric power from a healer power supply (not shown), whereby the water W is heated to a predetermined temperature via the mounting table 2. An electrode 7 is buried in the mounting table 2, and a bias voltage applying high-frequency power supply 9 is connected to the electrode 7 via a matcher 8. The bias voltage applying high-frequency power supply 9 applies high-frequency power (high-frequency bias) of 3 to 13.56 MHz, for example, 3 MHz, to the mounting table 2. The matcher 8 matches the load impedance with the internal (or output) impedance of the bias voltage applying high-frequency power supply 9. The matcher 8 serves to make sure that, when the plasma is generated in the chamber 1, the internal impedance of the bias voltage applying high-frequency power supply 9 apparently coincides with the load impedance.

Wafer support pins (not shown) for supporting and moving the wafer W up and down are provided in the mounting table 2 so as to protrude and retract with respect to the surface of the mounting table 2.

An exhaust pipe 23 is connected to a side surface of the exhaust chamber 11. An exhaust device 24 including a vacuum pump, an automatic pressure control valve and the like is connected to the exhaust pipe 23. By operating the vacuum pump of the exhaust device 24, the gas in the chamber 1 is uniformly discharged into the space 11a of the exhaust chamber 11 and is exhausted through the exhaust pipe 23, whereby the inside of the chamber 1 is controlled to a predetermined degree of vacuum by the automatic pressure control valve.

A loading/unloading port 25 for loading and unloading the wafer W into and from a vacuum transfer chamber (not shown) adjacent to the film forming apparatus 100 is provided in the side wall of the chamber 1. The loading/unloading port 25 is opened and closed by agate valve 26.

An upper portion of the chamber 1 is an opening portion, and a peripheral edge portion of the opening portion is a ring-shaped support portion 27. The microwave plasma source 20 is supported by the support portion 27.

The microwave plasma source 20 includes a disk-shaped microwave transmitting plate 28 made of a dielectric material, for example, ceramic such as quartz Al₂O₃, or the like, a planar slot antenna 31 having a plurality of slots, a retardation member 33, a coaxial waveguide 37, a mode converter 38, a waveguide 39, and a microwave generator 40.

The microwave transmitting plate 28 is airtightly provided in the support portion 27 via a sealing member 29. Therefore, the chamber 1 is kept airtight.

The planar slot antenna 31 is formed into a disk shape corresponding to the microwave transmitting plate 28 and is provided so as to make close contact with the microwave transmitting plate 28. The planar slot antenna 31 is locked to the upper end of the side wall of the chamber 1. The planar slot antenna 31 is composed of a circular plate made of an electric conductive material.

The planar slot antenna 31 is composed of, for example, a copper or aluminum plate whose surface is plated with silver or gold. The planar slot antenna 31 is configured so that a plurality of slots 32 for emitting microwaves is formed to penetrate the planar slot antenna 31 in a predetermined pattern. The pattern of the slots 32 is appropriately set so as to make sure that the microwaves are evenly radiated. Examples of the pattern include a pattern in which plural pairs of slots 32, each pair having two slots 32 arranged in a T shape, are disposed concentrically. The length and the arrangement interval of the slots 32 are determined according to the effective wavelength (λg) of a microwave. For example, the slots 32 are disposed so that the intervals thereof are λg/4, λg/2 or λg. The slots 32 may have another shape such as a circular shape, an arc shape or the like. In addition, the arrangement form of the slots 32 is not particularly limited. The slots 32 may also be disposed, for example, in a spiral shape or a radial shape, in addition to a concentric shape.

The retardation member 33 is provided in close contact with the upper surface of the planar slot antenna 31. The retardation member 33 is made of a dielectric material having a dielectric constant larger than that of vacuum, for example, quartz, ceramic (Al₂O₃), or a resin such as polytetrafluoroethylene, polyimide or the like. The retardation member 33 has a function of making the wavelength of a microwave shorter than that in the vacuum so as to reduce the size of the planar slot antenna 31.

The thicknesses of the microwave transmitting plate 28 and the retardation member 33 are adjusted such that the equivalent circuit formed by the retardation member 33, the planar slot antenna 31, the microwave transmitting plate 28 and the plasma satisfies the resonance conditions. By adjusting the thickness of the retardation member 33, it is possible to adjust the phase of a microwave. By adjusting the thickness so that the junction of the planar slot antenna 31 becomes an “antinode” of a standing wave, the microwave reflection is minimized and the microwave radiant energy is maximized. In addition, by making the retardation member 33 and the microwave transmitting plate 28 from the same material, it is possible to prevent interface reflection of a microwave.

The planar slot antenna 31 and the microwave transmitting plate 28 may be spaced apart from each other, and the retardation member 33 and the planar slot antenna 31 may be spaced apart from each other.

On the upper surface of the chamber 1, a cooling jacket 34 made of, for example, a metallic material such as aluminum, stainless steel, copper or the like is provided so as to cover the planar slot antenna 31 and the retardation member 33. A cooling water flow path 34a is formed in the cooling jacket 34. By allowing the cooling water to flow through the cooling water flow path 34a, it is possible to cool the retardation member 33, the planar slot antenna 31 and the microwave transmitting plate 28.

The coaxial waveguide 37 is inserted toward the microwave transmitting plate 28 from above a central opening of an upper wall of the cooling jacket 34. In the coaxial waveguide 37, an inner conductor 37a having a hollow rod shape and an outer conductor 37b having a cylindrical shape are arranged concentrically. The lower end of the inner conductor 37a is connected to the planar slot antenna 31. The coaxial waveguide 37 extends upward. The mode converter 38 is connected to the upper end of the coaxial waveguide 37. One end of a waveguide 39 having horizontally extending rectangular shape is connected to the mode converter 38. The microwave generator 40 is connected to the other end of the waveguide 39. A matching circuit 41 is interposed in the waveguide 39.

For example, the microwave generator 40 generates a microwave having a frequency of, for example, 2.45 GHz. The generated microwave propagates through the waveguide 39 in a TE mode. The vibration mode of the microwave is changed from the TE mode to a TEM mode by the mode converter 38. The microwave propagates toward the retardation member 33 via the coaxial waveguide 37. Then, the microwave spreads radially outward through the retardation member 33. The microwave is radiated from the slots 32 of the planar slot antenna 31 and is transmitted through the microwave transmitting plate 28 to generate an electric field in a region directly under the microwave transmitting plate 28 in the chamber 1, thereby generating microwave plasma. On a part of the lower surface of the microwave transmitting plate 28, an annular concave portion 28a recessed in a tapered shape is formed in order to facilitate generation of a standing wave due to the introduced microwave. Thus, the microwave plasma can be efficiently generated.

In addition to the frequency of 2.45 GHz, various frequencies such as 8.35 GHz, 1.98 GHz, 860 MHz, 915 MHz and the like may be used as the frequency of the microwave. Further, the microwave power is preferably 2000 to 5000 W, and the power density is preferably 2.8 to 7.1 W/cm².

The film forming apparatus 100 includes a gas supply mechanism 6 for supplying a processing gas which contains a boron-containing gas. The processing gas includes a boron-containing gas, a rare gas for plasma excitation and an etching gas. The processing gas may further include a hydrogen gas or the like. Examples of the boron-containing gas include a diborane (B₂H₆) gas, a boron trichloride (BCl₃) gas, an alkylborane gas, a decaborane gas and the like, which are described above. As the rare gas for plasma excitation, it may be possible to use an Ar gas, a He gas or both. As the etching gas, it may be possible to use an Ar gas or a F-based gas such as an excited NF₃ gas or the like.

In this example, a case where a B₂H₆ gas is used as the boron-containing gas and an Ar gas is used as the rare gas for plasma excitation and as the etching gas will be described by way of example.

The gas supply mechanism 6 includes a first gas supply part 61 for discharging a gas toward the center of the wafer W and a second gas supply part 62 for discharging a gas from the outside of the wafer W. The first gas supply part 61 includes a gas flow path 63 formed inside the mode converter 38 and the inner conductor 37a of the coaxial waveguide 37. A gas supply port 64 formed at the tip of the gas flow path 63 is opened into the chamber 1, for example, in the central portion of the microwave transmitting plate 28. Pipes 65 and 66 are connected to the gas flow path 63. A B₂H₆ gas supply source 68 for supplying a B₂H₆ gas as a boron-containing gas is connected to the pipe 65, and an Ar gas supply source 69 for supplying an Ar gas for plasma excitation and for etching is connected to the pipe 66. A flow rate controller 65a such as a mass flow controller or the like and an opening/closing valve 65b are provided in the pipe 65. A flow rate controller 66a and an opening/closing valve 66b are provided in the pipe 66.

The second gas supply part 62 includes a shower ring 71 provided in a ring shape along the inner wall of the chamber 1. The shower ring 71 is provided with an annular buffer chamber 72 and a plurality of gas discharge ports 73 provided at equal intervals from the buffer chamber 72 so as to face the inside of the chamber 1. Pipes 74 and 75 are branched from the pipes 65 and 66, respectively. The pipes 74 and 75 are joined together and are connected to the buffer chamber 72 of the shower ring 71. A flow rate controller 74a and an opening/closing valve 74b are provided in the pipe 74. A flow rate controller 75a and an opening/closing valve 75b are provided in the pipe 75.

In this example, the first gas supply part 61 and the second gas supply part 62 are supplied with a same type of gas supplied from the gas supply sources 68 and 69, in a state that the flow rate of each gas is respectively adjusted. The gas is discharged into the chamber 1 from the center of the microwave transmitting plate 28 and the peripheral edge of the chamber 1, respectively. Meanwhile, different gases may be supplied from the first gas supply part 61 and the second gas supply part 62, and the flow rate ratio thereof or the like may be individually adjusted.

The gas supply mechanism 6 includes all of the first and second gas supply parts 61 and 62, the B₂H₆ gas supply source 68, the Ar gas supply source 69, the pipes, the flow rate controllers, the valves and the like.

The film forming apparatus 100 includes a controller 50. The controller 50 controls the respective components of the film forming apparatus 100, for example, the valves, the flow rate controllers, the microwave generator 40, the heater power supply, the bias voltage applying high-frequency power supply 9, and the like. The controller 50 has a main controller having a CPU, an input device, an output device, a display device, and a memory device. In the memory device, there is set a storage medium that stores a program for controlling a process to be executed in the film forming apparatus 100, i.e., a process recipe. The main controller calls a predetermined process recipe stored in the storage medium and controls the film forming apparatus 100 to perform a predetermined process based on the process recipe.

When carrying out the method of the first embodiment in the film forming apparatus 100 configured as described above, first, the gate valve 26 is opened and the wafer W having the structure of FIG. 1A is loaded into the chamber 1. The wafer W is mounted on the mounting table 2, and the gate valve 26 is closed.

At this time, the mounting table temperature is set to 500 degrees C. or lower (60 to 500 degrees C.), for example 300 degrees C. The interior of the chamber 1 is purged. The pressure in the chamber 1 is set to a predetermined pressure. The temperature of the wafer W is stabilized. Thereafter, a microwave of 2000 to 5000 W (2.8 to 7.1 W/cm²), for example, 3500 W (5.0 W/cm²) is introduced from the microwave generator 40 to ignite plasma. Then, the inner pressure of the chamber 1 is regulated to 0.67 Pa to 33.3 Pa (5 mTorr to 250 mTorr), for example 6.7 Pa (50 mTorr). A B₂H₆ gas (B₂H₆ concentration: 10 vol %) is supplied from the first gas supply part 61 and the second gas supply part 62 at a flow rate of 100 to 1000 sccm, for example 500 sccm, to form a boron film having a film thickness of, for example, 1 to 10 nm.

After the formation of the boron film is completed, the supply of the B₂H₆ gas is stopped while maintaining the microwave plasma. While evacuating the inside of the chamber 1, the interior of the chamber 1 is purged with an Ar gas. While supplying an Ar gas as an etching gas at a flow rate of 100 to 1000 sccm, for example 500 sccm, a high frequency bias of 100 to 2000 W, for example, 500 W is applied from the bias voltage applying high-frequency power supply 9, whereby side etching by Ar ions in the Ar plasma is performed.

The boron film formation and the side etching are performed once or repeated a predetermined number of times to form a boron film in a self-aligned and selective manner.

### One Example of Film Forming Apparatus for Carrying Out the Method of the Second Embodiment

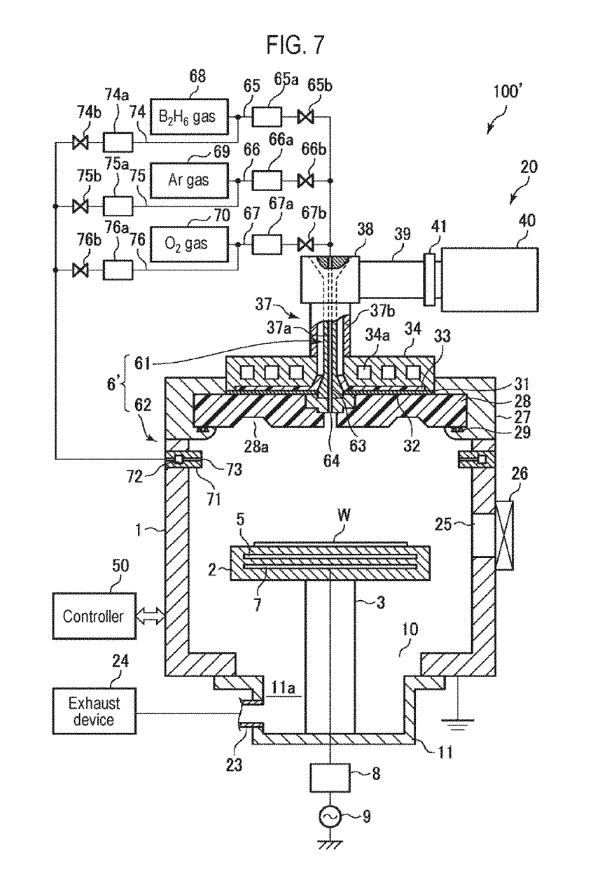

Next, an example of a film forming apparatus for carrying out the selective film forming method of the second embodiment will be described. FIG. 7 is a sectional view showing an example of a film forming apparatus for carrying out the selective film forming method of the second embodiment. The film forming apparatus 100′ of this example is configured as a microwave plasma apparatus for forming a boron oxide film by performing formation of a boron film, side etching and oxidation of the boron film.

This film forming apparatus 100′ has the same configuration as the film forming apparatus 100, except that the film forming apparatus 100 includes a gas supply mechanism 6′ instead of the gas supply mechanism 6 of the film forming apparatus 100. Therefore, in FIG. 7, the same components as those of the film forming apparatus 100 of FIG. 6 are designated by like reference numerals, and description thereof will be omitted.

In the film forming apparatus 100′, the gas supply mechanism 6′ is configured to supply a processing gas which contains a boron-containing gas. The processing gas includes a boron-containing gas, a rare gas for plasma excitation, an etching gas and an oxidizing gas. The processing gas may further include a hydrogen gas or the like. Examples of the boron-containing gas include a diborane (B₂H₆) gas, a boron trichloride (BCl₃) gas, an alkylborane gas, a decaborane gas and the like, which are described above. As the rare gas for plasma excitation, it may be possible to use an Ar gas, a He gas or both. As the etching gas, it may be possible to use an Ar gas or a F-based gas such as an excited NF₃ gas or the like. As the oxidizing gas, it may be possible to use an O₂ gas, an O₃ gas, a N₂O gas or the like.

In this example, a case where a B₂H₆ gas is used as the boron-containing gas, an Ar gas is used as the rare gas for plasma excitation and as the etching gas, and an O₂ gas is used as the oxidizing gas, will be described by way of example.

Just like the gas supply mechanism 6, the gas supply mechanism 6′ includes a first gas supply part 61 for discharging a gas toward the center of the wafer W and a second gas supply part 62 for discharging a gas from the outside of the wafer W. The first gas supply part 61 includes a gas flow path 63 formed inside the mode converter 38 and the inner conductor 37a of the coaxial waveguide 37. A gas supply port 64 formed at the tip of the gas flow path 63 is opened into the chamber 1, for example, in the central portion of the microwave transmitting plate 28. In addition to the pipes 65 and 66, a pipe 67 is connected to the gas flow path 63. A B₂H₆ gas supply source 68 for supplying a B₂H₆ gas as a boron-containing gas is connected to the pipe 65. An Ar gas supply source 69 for supplying an Ar gas for plasma excitation and for etching is connected to the pipe 66. An O₂ gas supply source 70 for supplying an O₂ gas as an oxidizing gas is connected to the pipe 67. A flow rate controller 65a such as a mass flow controller or the like and an opening/closing valve 65b are provided in the pipe 65. A flow rate controller 66a and an opening/closing valve 66b are provided in the pipe 66. A flow rate controller 67a and an opening/closing valve 67b are provided in the pipe 67.

As in the film forming apparatus 100, the second gas supply part 62 includes a shower ring 71. The shower ring 71 is provided with an annular buffer chamber 72 and a plurality of gas discharge ports 73 provided at equal intervals from the buffer chamber 72 so as to face the inside of the chamber 1. Pipes 74, 75 and 76 are branched from the pipes 65, 66 and 67, respectively. The pipes 74, 75 and 76 are joined together and are connected to the buffer chamber 72 of the shower ring 71. A flow rate controller 74a and an opening/closing valve 74b are provided in the pipe 74. A flow rate controller 75a and an opening/closing valve 75b are provided in the pipe 75. A flow rate controller 76a and an opening/closing valve 76b are provided in the pipe 76.

In this example, the first gas supply part 61 and the second gas supply part 62 are supplied with a same type of gas such as a boron-containing gas, a rare gas, and an oxidizing gas, which are supplied from the gas supply sources 68, 69 and 70, respectively, in a state that the flow rate of each gas is respectively adjusted. The boron-containing gas, the rare gas and the oxidizing gas are discharged into the chamber 1 from the center of the microwave transmitting plate 28 and the peripheral edge of the chamber 1, respectively. Meanwhile, different gases may be supplied from the first gas supply part 61 and the second gas supply part 62, and the flow rate ratio thereof or the like may be individually adjusted.

The gas supply mechanism 6′ includes all of the first and second gas supply parts 61 and 62, the B₂H₆ gas supply source 68, the Ar gas supply source 69, the O₂ gas supply source 70, the pipes, the flow rate controllers, the valves and the like.

When carrying out the method of the second embodiment in the film forming apparatus 100′ configured as above, the gate valve 26 is first opened and the wafer W having the structure of FIG. 4A is loaded into the chamber 1. The wafer W is mounted on the mounting table 2, and the gate valve 26 is closed.

At this time, the mounting table temperature is set to 500 degrees C. or lower (60 to 500 degrees C.), for example 300 degrees C. The interior of the chamber 1 is purged. The pressure in the chamber 1 is set to a predetermined pressure. The temperature of the wafer W is stabilized. Thereafter, a microwave of 2000 to 5000 W (2.8 to 7.1 W/cm²), for example, 3500 W (5.0 W/cm²) is introduced from the microwave generator 40 to ignite plasma. Then, the inner pressure of the chamber 1 is regulated to 0.67 Pa to 33.3 Pa (5 mTorr to 250 mTorr), for example 6.7 Pa (50 mTorr). A B₂H₆ gas (B₂H₆ concentration: 10 vol %) is supplied from the first gas supply part 61 and the second gas supply part 62 at a flow rate of 100 to 1000 sccm, for example 500 sccm, to form a boron film having a film thickness of, for example, 1 to 10 nm.

After the formation of the boron film is completed, the supply of the B₂H₆ gas is stopped while maintaining the microwave plasma. While evacuating the inside of the chamber 1, the interior of the chamber 1 is purged with an Ar gas. While supplying an Ar gas as an etching gas at a flow rate of 100 to 1000 sccm, for example 500 sccm, a high frequency bias of 100 to 2000 W, for example, 500 W is applied from the bias voltage applying high-frequency power supply 9, whereby side etching by Ar ions in the Ar plasma is performed.

After the side etching is finished, an O₂ gas as an oxidizing gas is supplied at a flow rate of 10 to 1000 sccm, for example 100 sccm, while maintaining the microwave plasma. Thus, O₂ plasma is generated by microwave plasma to oxidize the boron film. As a result, the boron film becomes a boron oxide film.

The boron film formation, the side etching and the oxidation process are performed once, or the boron film formation and the side etching are repeated a predetermined number of times and the oxidation process is performed at an appropriate timing, thereby a boron oxide film is formed in a self-aligned and selective manner.

### <Other Applications>

Although the embodiments of the present disclosure have been described above, the present disclosure is not limited to the above-described embodiments, and various modifications may be made within the scope of idea of the present disclosure.

For example, in the above-described embodiments, there has been described the example where the film formation is performed by the microwave plasma processing apparatus. However, the plasma CVD method is not limited, and plasma CVD by a method other than that of the above embodiments may be used.

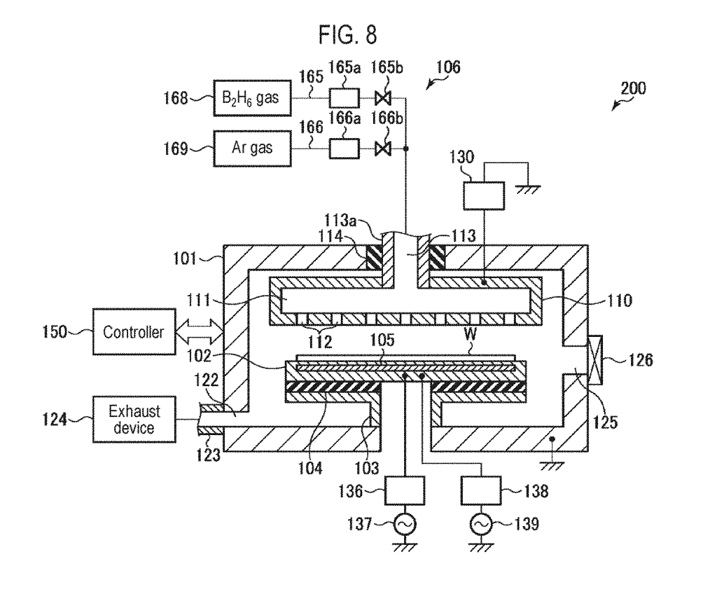

As another processing apparatus, it may be possible to use a capacitively coupled parallel plate plasma apparatus shown in FIG. 8. The apparatus of FIG. 8 is configured as a film forming apparatus for carrying out the method of the first embodiment.

The film forming apparatus 200 of FIG. 8 includes a substantially cylindrical chamber 101 which is airtightly configured and grounded. The chamber 101 is made of a metallic material such as, for example, aluminum, alloy thereof or the like.

In the bottom portion of the chamber 101, there is provided a mounting table 102 which serves as a lower electrode and horizontally supports the wafer W as a substrate to be processed. The mounting table 102 is supported via a metallic support member 103 and an insulating member 104 which are arranged on the bottom surface of the chamber 101. Furthermore, a resistance heating type heater 105 is buried in the mounting table 102. The heater 105 generates heat by being supplied with electric power from a heater power supply (not shown), whereby the wafer W is heated to a predetermined temperature via the mounting table 102.

A gas shower head 110 serving as an upper electrode is provided in the upper portion inside the chamber 101 so as to face the mounting table 102. The gas shower head 110 is made of a metal and has a disc shape. A gas diffusion space 111 is formed inside the gas shower head 110. A plurality of gas discharge holes 112 are formed on the lower surface of the gas shower head 110.

A gas flow path 113 is connected to the center of the upper surface of the gas shower head 110. A gas pipe 113a constituting the gas flow path 113 is fixed to the chamber 101 via an insulating member 114. The gas shower head 110 is supported on the chamber 101 by the gas pipe 113a.

Pipes 165 and 166 are connected to the gas flow path 113. A B₂H₆ gas supply source 168 for supplying a B₂H₆ gas as a boron-containing gas is connected to the pipe 165. An Ar gas supply source 169 for supplying an Ar gas as a rare gas for plasma excitation and as an etching gas is connected to the pipe 166. A B₂H₆ gas and an Ar gas are supplied from the gas supply sources 168 and 169 to the gas diffusion space 111 of the gas shower head 110 through the pipes 165 and 166 and the gas flow path 113 and are discharged from the gas discharge holes 112 toward the wafers W in the chamber 101.

A flow rate controller 165a such as a mass flow controller or the like and an opening/closing valve 165b are provided in the pipe 165. A flow rate controller 166a and an opening/closing valve 166b are provided in the pipe 166.

The gas shower head 110, the gas supply sources 168 and 169, and the pipes 165 and 166 constitute a gas supply mechanism 106.

An exhaust port 122 is provided in the lower portion of the side wall of the chamber 101, and an exhaust pipe 123 is connected to the exhaust port 122. An exhaust device 124 including a vacuum pump, an automatic pressure control valve and the like is connected to the exhaust pipe 123. By operating the vacuum pump of the exhaust device 124, the gas in the chamber 101 is exhausted via the exhaust pipe 123, and the inside pressure of the chamber 101 is controlled to a predetermined degree of vacuum by the automatic pressure control valve.

A loading/unloading port 125 for loading and unloading a wafer W into and from a vacuum transfer chamber (not shown) adjacent to the film forming apparatus 200 is provided in the side wall of the chamber 101. The loading/unloading port 125 is opened and closed by a gate valve 126.

A plasma-generating high-frequency power supply 137 for supplying a first high-frequency power of a first frequency for plasma generation and a bias-voltage-applying high-frequency power supply 139 for supplying a second high-frequency power of a second frequency lower than the first frequency are connected to the mounting table 102. The plasma-generating high-frequency power supply 137 is electrically connected to the mounting table 102 via a first matcher 136. The bias-voltage-applying high-frequency power supply 139 is electrically connected to the mounting table 102 via a second matcher 138. The plasma-generating high-frequency power supply 137 applies the first high-frequency power of 40 MHz or more, for example, 60 MHz, to the mounting table 102. The bias-voltage-applying high-frequency power supply 139 applies the second high-frequency power of 3 to 13.56 MHz, for example, 3 MHz, to the mounting table 102. The first high-frequency power may be applied to the gas shower head 110. An impedance adjustment circuit 130 is connected to the gas shower head 110.

The first matcher 136 matches the load impedance with the internal (or output) impedance of the plasma-generating high-frequency power supply 137. The first matcher 136 serves to make sure that, when plasma is generated in the chamber 101, the output impedance of the plasma-generating high-frequency power supply 137 apparently matches with the load impedance. The second matcher 138 matches the load impedance with the internal (or output) impedance of the bias-voltage-applying high-frequency power supply 139. The second matcher 138 serves to make sure that, when plasma is generated in the chamber 101, the internal impedance of the bias-voltage-applying high-frequency power supply 139 apparently matches with the load impedance.

By increasing the frequency of the plasma-generating high-frequency power supply 137 to 40 MHz or more and providing the impedance adjustment circuit 130, it is possible to reduce the impact of ions on the wafer W and to suppress the increase in the surface roughness of the boron film.

The film forming apparatus 200 includes a controller 150. The controller 150 controls the respective components of the film forming apparatus 200, for example, the valves, the flow rate controllers, the heater power supply, the high-frequency power supplies 137 and 139, and the like. The controller 150 has a main controller having a CPU, an input device, an output device, a display device, and a memory device. In the memory device, there is set a storage medium that stores a program for controlling a process to be executed in the film forming apparatus 200, i.e., a process recipe. The main controller calls a predetermined process recipe stored in the storage medium and controls the film forming apparatus 200 to perform a predetermined process based on the process recipe.

When carrying out the method of the first embodiment in the film forming apparatus 200 configured as described above, first, the gate valve 126 is opened and the wafer W is loaded into the chamber 101. The water W is mounted on the mounting table 102, and the gate valve 126 is closed.

Then, boron film formation and side etching are performed by the same sequence as that of the apparatus of FIG. 6. The gas flow rate, pressure and temperature at this time are also the same as those of the apparatus of FIG. 6. Only the plasma generation method and conditions are different.

The boron film formation and side etching described above are repeated a predetermined number of tunes to form a boron film in a self-aligned and selective manner.

In the film forming apparatus as shown in FIG. 8, by adding the O₂ gas supply source and the pipe to the gas supply mechanism 106 and providing the function of supplying an O₂ gas to the gas shower head 110, it is also possible to form the boron oxide film of the second embodiment in a self-aligned and selective manner.

The present disclosure is not limited to the modification shown in FIG. 8 and the present disclosure can be carried out by a plasma CVD apparatus having various other configurations.

In the above-described embodiment, there has been shown an example where the boron-based film formation and side etching of the first embodiment are performed in the same apparatus, and the boron film formation, side etching and oxidation of the second embodiment are performed in the same apparatus. However, all or a part of the boron film formation, side etching and oxidation may be performed in different apparatuses.

According to one embodiment of the present disclosure, by forming a boron-based film on a work piece having a plurality of recesses by plasma CVD, the boron-based film is selectively formed in the portion other than the recesses. Thereafter, by etching the side surface of the boron-based film, the boron-based film is formed in the portion other than the recesses of the work piece in a self-aligned and selective manner. Therefore, it is possible to selectively form a film having a higher etching resistance than a conventional one without having to use a special process or apparatus.

In addition, according to another embodiment of the present disclosure, by forming a boron-based film on a work piece having a plurality of recesses by plasma CVD, the boron-based film is selectively formed in the portion other than the recesses. Thereafter, by etching and the side surface of the boron-based film and oxidizing, a boron oxide film is formed in the portion other than the recesses of the work piece in a self-aligning and selective manner. Therefore, it is possible to selectively form a film having a higher etching resistance than a conventional one without having to use a special process or apparatus. Moreover, boron oxide can be easily removed by water since it is water-soluble.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A selective film forming method, comprising:
a first step of preparing a work piece having a plurality of recesses;
a second step of forming a boron-based film having a first predetermined film thickness in a portion of the work piece other than the recesses by plasma CVD; and
a third step of etching a side surface of the formed boron-based film having the first predetermined film thickness,
wherein the boron-based film is formed in the portion of the work piece other than the recesses in a self-aligned and selective manner.

2. The method of claim 1, wherein the second step and the third step are repeated a predetermined number of times to form the boron-based film having a second predetermined film thickness in the portion of the work piece other than the recesses in a self-aligned and selective manner.

3. The method of claim 1, wherein in the second step, as the boron-based film, a boron film containing boron and unavoidable impurities is formed.

4. The method of claim 1, wherein the second step and the third step are performed in a same chamber.

5. A selective film forming method, comprising:
a first step of preparing a work piece having a plurality of recesses;
a second step of selectively forming a boron film having a first predetermined film thickness in a portion of the work piece other than the recesses by plasma CVD;
a third step of etching a side surface of the formed boron film having the first predetermined film thickness; and
a fourth step of performing an oxidation process on the boron film,
wherein a boron oxide film is formed in the portion of the work piece other than the recesses in a self-aligned and selective manner.

6. The method of claim 5, wherein, while the second step and the third step are repeated a predetermined number of times, the fourth step is performed at a predetermined timing to form the boron oxide film having a second predetermined film thickness in a self-aligned and selective manner.

7. The method of claim 6, wherein the second step, the third step and the fourth step are sequentially repeated.

8. The method of claim 6, wherein a cycle of performing the fourth step, after repeating the second step and the third step the predetermined number of times, is repeated a plurality of times.

9. The method of claim 6, wherein after repeating the second step and the third step until the boron film reaches a third predetermined film thickness, the fourth step is performed.

10. The method of claim 5, wherein a film thickness of the boron film to be oxidized when performing the fourth step is 10 nm or less.

11. The method of claim 5, wherein the fourth step is performed by O₂ plasma.

12. The method of claim 5, wherein the second step, the third step and the fourth step are performed in a same chamber.

13. The method of claim 1, wherein in the second step, a B₂H₆ gas as a boron-containing gas is supplied to the work piece.

14. The method of claim 1, wherein in the second step, a rare gas for plasma excitation is supplied to the work piece.

15. The method of claim 1, wherein the second step is performed by microwave plasma.

16. The method of claim 1, wherein the second step is performed at a pressure of 0.67 to 33.3 Pa and at a temperature of 500 degrees C. or lower.

17. The method of claim 1, wherein the third step is performed by argon plasma or a fluorine-containing gas.

18. A film forming apparatus, comprising:
a chamber configured to accommodate a work piece having a plurality of recesses;
a mounting table configured to support the work piece in the chamber;
a gas supply mechanism configured to supply a processing gas including at least a boron-containing gas and an etching gas into the chamber;
an exhaust device configured to evacuate an inside of the chamber;
a plasma generator configured to generate plasma in the chamber; and
a controller configured to perform control so that a boron-based film is formed in a portion of the work piece other than the recesses by causing the gas supply mechanism to supply the processing gas including the boron-containing gas into the chamber and by causing the plasma generator to generate plasma of the processing gas including the boron-containing gas, and a side surface of the boron-based film is etched by causing the gas supply mechanism to supply the etching gas into the chamber,
wherein the boron-based film is formed in the portion of the work piece other than the recesses in a self-aligned and selective manner.

19. A film forming apparatus, comprising:
a chamber configured to accommodate a work piece having a plurality of recesses;
a mounting table configured to support the work piece in the chamber;
a gas supply mechanism configured to supply a processing gas including at least a boron-containing gas, an etching gas and an oxidizing gas into the chamber;
an exhaust device configured to evacuate an inside of the chamber;
a plasma generator configured to generate plasma in the chamber; and
a controller configured to perform control so that a boron film is selectively formed in a portion of the work piece other than the recesses by causing the gas supply mechanism to supply the processing gas including the boron-containing gas into the chamber and by causing the plasma generator to generate plasma of the processing gas including the boron-containing gas, a side surface of the boron film is etched by causing the gas supply mechanism to supply the etching gas into the chamber, and the boron film is oxidized by causing the plasma generator to generate plasma of the oxidizing gas,
wherein a boronoxide film is formed in the portion of the work piece other than the recesses in a self-aligned and selective manner.
